(19) United States
(12) Patent Application Publication
(10) Pub. No.: US 2024/0353500 A1
(43) Pub. Date: Oct. 24, 2024

(54) FAULT DETECTION IN REMOTE POWERING SYSTEMS USING LOAD CURRENT PULSE CHARACTERISTICS

(71) Applicant: ALPHA TECHNOLOGIES LTD., Burnaby (CA)

(72) Inventors: Marco Andres Bianchi, British Columbia (CA); Francisco Paz, British Columbia (CA); Peter Ksiazek, British Columbia (CA); Rahul Khandekar, British Columbia (CA)

(73) Assignee: ALPHA TECHNOLOGIES LTD., Burnaby (CA)

(21) Appl. No.: 18/137,711

(22) Filed: Apr. 21, 2023

(51) Int. Cl. G01R 31/40

(52) U.S. Cl. CPC G01R 31/40

(57) ABSTRACT

Devices, methods, and systems for detecting a fault in an electrical power system which includes a source-side converter in communication with a load-side converter via a transmission line. An output current from the source-side converter to the load-side converter over the transmission line is measured during a time period from a beginning of a first current pulse of the output current to a beginning of a second current pulse of the output current. An output voltage of the source-side converter is reduced, responsive to a profile of the output current differing from an expected profile of the output current during the time period. In some implementations, the expected profile of the output current includes a current limit, and the output current differs from the expected profile by exceeding the current limit during the first current pulse.

### FIELD OF INVENTION

The present invention relates to electrical power distribution, and particularly to fault detection in the context of electrical power distribution.

### BACKGROUND

When transmitting power over large distances it is advantageous to reduce the current through the cable to reduce losses. However, standards and codes limit the amount of power that can be transmitted in telecommunication cabling when the voltage exceeds 150V (60V indoors). These voltage limits exist to protect operators and the public from harm due to accidental contact with conductors. New standards are currently being drafted which allow for power circuits that can detect faults and protect against accidental contact.

### BRIEF DESCRIPTION OF THE DRAWINGS

FIG. 1 is a system diagram which shows portions of an example remote power system;

FIG. 2 is a system diagram which shows portions of another example remote power system;

FIG. 3 is a line graph which shows the output voltage and output current of an upconverter and current due to faults in the power system of FIG. 2, under non-fault conditions;

FIG. 4 is a line graph which shows the output voltage and output current of an upconverter and current due to faults in the power system of FIG. 2, under low-impedance fault conditions;

FIG. 5 is a line graph which shows the output voltage and output current of an upconverter and current due to faults in the power system of FIG. 2, under high-impedance fault conditions;

FIG. 6 is a line graph illustrating behavior of a system where, instead of drawing a current pulse with a fixed amplitude and a variable on-time, the downconverter draws a current pulse with an indeterminate amplitude and a fixed on-time, and current measurement for fault detection occurs during current off-time but not during current on-time.

FIG. 7 is a line graph illustrating behavior of a system where, instead of drawing a current pulse with a fixed amplitude and a variable on-time, the downconverter draws continuous current flow at specific quantized current levels;

FIG. 8 is a line graph illustrating behavior of a system where, instead of drawing a current pulse with a fixed amplitude and a variable on-time, the downconverter draws current flow at specific quantized current levels during current pulses having a fixed on-time;

FIG. 9 is a line graph illustrating behavior of a system similar to FIG. 9, except in that the downconverter draws current flow at specific quantized current levels during current pulses having a variable on-time;

FIG. 10 is a line graph illustrating behavior of a system similar to FIG. 10, except in that, further to drawing a current flow at specific quantized current levels during current pulses having a variable tₒₙ, the current pulses occur at a fixed frequency;

FIG. 11 is a line graph illustrating behavior of a system similar to FIGS. 2-6 above, except in the upconverter tracks a total of any measured mismatch between the measured current predefined current pulse shape during on-time and any measured current exceeding a threshold during off-time and a fault is detected when the tracked total mismatch exceeds a threshold;

FIG. 12 is a system diagram which shows portions of the example remote power system of FIG. 2, further illustrating a junction box;

FIG. 13 is a system diagram which shows portions of the example remote power system of FIG. 2, further illustrating example bifurcation of upconverter and safety functions within the upconverter;

FIG. 14 is a system diagram which shows portions of the example remote power system of FIG. 2, further illustrating upconverter and safety functions implemented in separate devices; and

FIG. 15 is a flowchart illustrating an example procedure for detecting a fault in an electrical power system.

### DETAILED DESCRIPTION

Some implementations provide a method for detecting a fault in an electrical power system which includes a source-side converter in communication with a load-side converter via a transmission line. An output current from the source-side converter to the load-side converter over the transmission line is measured during a time period from a beginning of a first current pulse of the output current to a beginning of a second current pulse of the output current. An output voltage of the source-side converter is reduced, responsive to a profile of the output current differing from an expected profile of the output current during the time period.

In some implementations, the expected profile of the output current includes a current limit, and the output current differs from the expected profile by exceeding the current limit during the first current pulse. In some implementations, the expected profile of the output current includes a current limit and the output current differs from the expected profile by exceeding the current limit after the first current pulse and before the second current pulse. In some implementations, the expected profile of the output current includes a maximum current amplitude which varies during the time period. In some implementations, reducing the output voltage of the source-side converter includes disconnecting an output of the source-side converter from the transmission line. In some implementations, reducing the output voltage of the source-side converter includes turning off the source-side converter. In some implementations, the expected profile of the output current includes a predefined pulse shape of the output current. In some implementations, the expected profile includes a plurality of quantized current amplitudes. In some implementations, the output current differs from the expected profile by differing from all of the plurality of quantized current amplitudes. In some implementations, the expected profile of the output current includes a maximum accumulated quantity limit, where the quantity is derived from the measurement of the output current over time. In some implementations, an accumulated quantity is tracked based on a difference between the output current and the expected profile, where the profile of the output current differs from the expected profile of the output current when the accumulated quantity exceeds a threshold. In some implementations, the source-side converter includes a power converter. In some implementations, the load-side converter includes a power converter.

Some implementations provide a device configured to detect a fault in an electrical power system that includes a source-side converter in communication with a load-side converter via a transmission line. The device includes circuitry configured to measure an output current from the source-side converter to the load-side converter over the transmission line during a time period from a beginning of a first current pulse of the output current to a beginning of a second current pulse of the output current. The device also includes circuitry configured to reduce an output voltage of the source-side converter in response to a profile of the output current differing from an expected profile of the output current during the time period.

In some implementations, the expected profile of the output current includes a current limit, and the output current differs from the expected profile by exceeding the current limit during the first current pulse. In some implementations, the expected profile of the output current includes a current limit and the output current differs from the expected profile by exceeding the current limit after the first current pulse and before the second current pulse. In some implementations, the expected profile of the output current includes a maximum current amplitude which varies during the time period. In some implementations, reducing the output voltage of the source-side converter includes disconnecting an output of the source-side converter from the transmission line. In some implementations, reducing the output voltage of the source-side converter includes turning off the source-side converter. In some implementations, the expected profile of the output current includes a predefined pulse shape of the output current. In some implementations, the expected profile includes a plurality of quantized current amplitudes. In some implementations, the output current differs from the expected profile by differing from all of the plurality of quantized current amplitudes. In some implementations, the expected profile of the output current includes a maximum accumulated quantity limit, where the quantity is derived from the measurement of the output current over time. In some implementations, the device includes circuitry configured to track an accumulated quantity based on a difference between the output current and the expected profile, and the profile of the output current differs from the expected profile of the output current when the accumulated quantity exceeds a threshold. In some implementations, the source-side converter includes a power converter. In some implementations, the load-side converter includes a power converter.

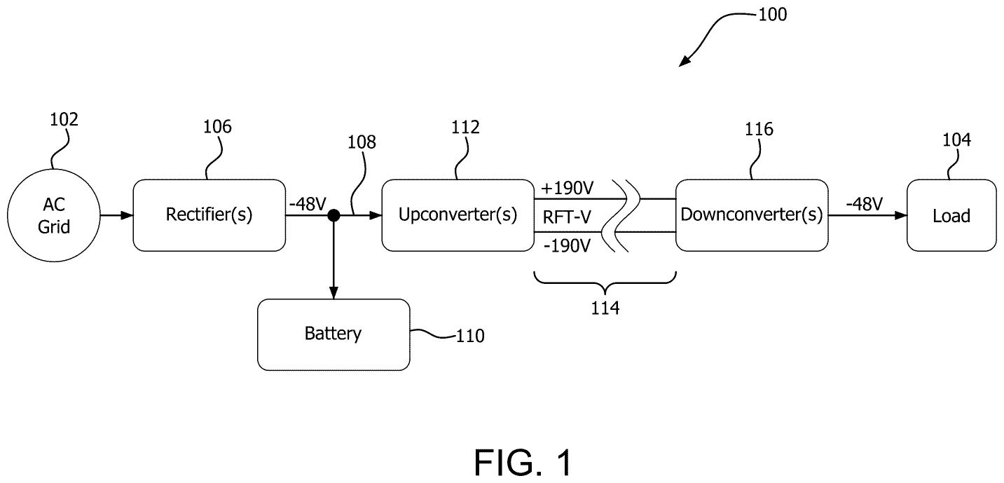

FIG. 1 is a system diagram which shows portions of an example remote power system 100 that provides electrical power from an AC grid 102 to a load 104. Remote power system 100 is a telecommunications remote power system in this example (i.e., a remote power system for telecommunications applications), however, remote power system 100 is usable in any suitable remote power application (e.g., telecommunication or non-telecommunication).

Remote power system 100 includes at least one AC to DC power converter 106. AC to DC power converter 106 receives AC power as an input from AC grid 102 and provides DC power to a distribution bus 108 as output. AC to DC power converters are typically referred to as rectifiers. The output of AC to DC power converter 106 has a nominal (e.g., rated) DC voltage. For example, in some implementations, the nominal DC voltage may be −48V, and the actual voltage may between −42V and −56V. It is noted that any suitable nominal and/or actual voltages are usable in different implementations. Any suitable circuitry, device, and/or devices for carrying electrical power may be used as, may be included in, and/or may be used in place of, distribution bus 108. Typically, a remote power system such as remote power system 100 includes at least one AC to DC power converter, such as AC to DC power converter 106, however, some implementations do not include an AC to DC power converter. For example, in some implementations, the system may be powered directly from a DC power source (e.g., via distribution bus 108) or in another manner other than via an AC to DC power converter.

Distribution bus 108 is connected to and/or in electrical communication with a battery 110 (e.g., a bank of batteries) that is configured to provide power on distribution bus 108 in the event that power ceases to be provided by AC grid 102 and/or AC to DC power converter 106 (e.g., in the event of a failure of AC grid 102 and/or AC to DC power converter 106). In some implementations, battery 110 may charge based on power from distribution bus 108 if power (e.g., typical power) is available on distribution bus 108, or based on power from another source. Any suitable electricity storage device or devices may be used as, may be included in, and/or may be used in place of, battery 110. In some implementations, battery 110 is omitted.

Distribution bus 108 is also connected to and/or in electrical communication with upconverter circuitry 112. Upconverter circuitry 112 is configured to receive the nominal voltage from AC to DC power converter 106 via distribution bus 108 and to convert the nominal voltage to a higher voltage (“transmission voltage”) for transmission over transmission line 114. In this example, upconverter circuitry 112 includes one or more Remote Feeding Telecommunication-Voltage (RFT-V) power modules (e.g., as defined in the IEC 60950-21 standard), and the RFT-V modules convert the nominal −48V into several output channels of +/−190V with a power limit of 100W per output channel. In some implementations, the per-channel power limit may be based on a safety standard, safety considerations, design considerations, and/or any other reason. It is noted that these voltage and power values are only examples, and any suitable transmission voltage and/or maximum channel power may be used in other implementations. In this example, each output channel is referred to as an RFT-V channel. It is noted that RFT-V channels are used for the sake of example, however, any suitable single or multi-channel upconverter may be used in other implementations. For example, other implementations may use other power-limited circuits such as RFT-C or NEC Class 2 circuits. It is noted that RFT-V is one example of a power limited circuit, and RFT-C and NEC Class 2 are other examples.

The outputs of upconverter circuitry 112 (i.e., the outputs of the RFT-V channels in this example) are connected to and/or in electrical communication with a pair of conductors of transmission line 114. Any suitable power transmission line or combination of lines, and/or circuitry, may be used as, may be included in, and/or may be used in place of transmission line 114. In some implementations, transmission line 114 may run, for example, for many thousands of feet to load 104 (e.g., via downconverter 116).

Transmission line 114 is also connected to and/or in electrical communication with downconverter circuitry 116. Downconverter circuitry 116 is configured to receive the transmission voltage from transmission line 114 and to convert the transmission voltage to a lower voltage. In this example, downconverter circuitry 116 converts the several channels of +/−190V transmission voltage back to the −48V nominal voltage with a power limit of 100W per channel. It is noted that these voltage and power values are for example only, and any suitable voltages may be used in other implementations. It is noted that the downconverter circuit must be compatible with the upconverter circuit (e.g., an RFT-V upconverter needs an RFT-V downconverter). In this context, compatible means that the downconverter and upconverter are sized to have power limits that can accommodate one another.

Load 104 includes any suitable electrical load, such as a telecommunications device. In some implementations where transmission power is limited (e.g., by safety standards), powering large loads such as a 5G small cell or mini-macro cell radio may be difficult. In some implementations, multiple channels (e.g., RFT-V channels) are aggregated at downconverter circuitry 116 to power larger loads. However, for relatively larger loads (e.g., a small cell site, e.g., requiring in excess of 1 kW), the system may require aggregation of an exceedingly large number of channels (e.g., upconverters, downconverter, and cables) and this may impact cost and feasibility.

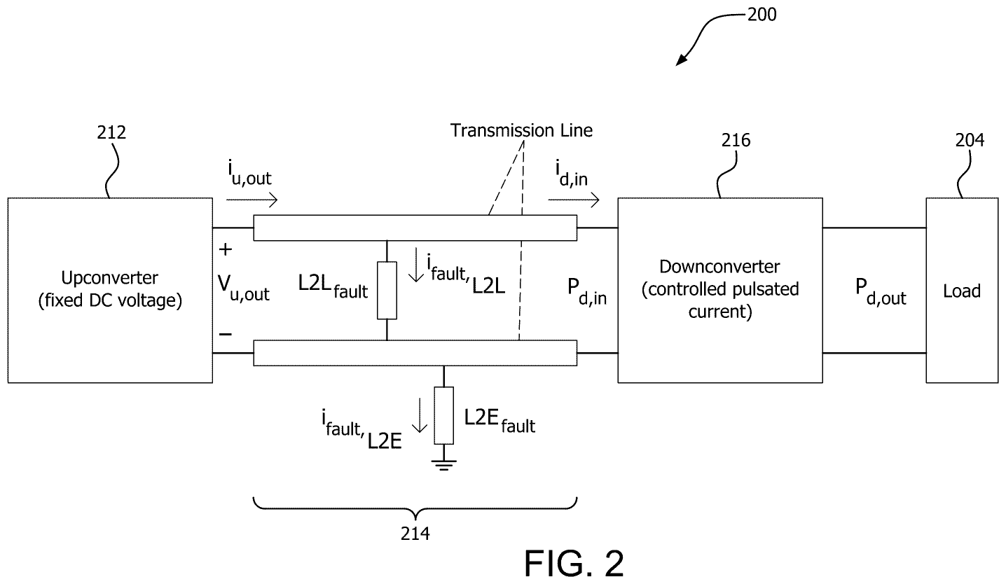

FIG. 2 is a system diagram which shows portions of an example remote power system 200. Remote power system 200 is a telecommunications remote power system in this example (i.e., a remote power system for telecommunications applications), however, in some implementations, remote power system 200 is usable in any suitable remote power application (e.g., telecommunication or non-telecommunication).

Remote power system 200 is similar to remote power system 100 except in that it replaces traditional RFT-V/C and NEC Class 2 circuits with circuitry that, in some implementations, allows for relatively higher power transfer capability, maintains line-to-line (L2L) and line-to-earth (L2E) fault detection and protection capabilities, and/or in some implementations is compatible with the requirements of Fault Managed Power Systems as envisioned by the ATIS 0600040 TR and UL1400-1 standards. It is noted that in this example, and throughout the examples herein, an upconverter appears on the source side of the transmission line, and a downconverter appears on the load-side of the transmission line. However, this is only an example. In other implementations, the converters can be any type of converter.

Two different types of electrical faults can occur in an electrical power system: Line-to-Earth (L2E) faults, and Line-to-Line (L2L) faults.

L2E faults occur when a fault (e.g., contact by a human body) occurs between earth and one of the lines (e.g., of transmission line 214). For instance, in example remote power system 200, an L2E fault may occur anywhere between the output of upconverter 212 and the input of downconverter 216. An example L2E fault is shown in FIG. 2. A defining characteristic of an L2E fault is that current flows from one of the lines, through the fault, to earth. Accordingly, there are various ways to detect L2E faults including, for example, measuring mismatches between current on different lines of the transmission line, measuring the earth current, and/or measuring any mismatch in the transmission line voltage caused by leakage current.

Accordingly, some implementations have the advantage of facilitating L2E faults.

L2L faults occur when a fault (e.g., contact by a human body) occurs across the lines of the transmission line, between output terminals of an upconverter, and/or between the input terminals of the downconverter. For instance, in example remote power system 200, an L2L fault may occur between transmission lines 214, between the output terminals of upconverter 212, and/or between the input terminals of downconverter. An example L2L fault is shown in FIG. 2. In some cases, L2L faults may be more difficult to detect than L2E faults in a typical power system because the fault current will simply add to the load current and appear as an increase in load. In such situations, if the fault is relatively low in impedance, then an over-current condition may exist that may be easy to detect. However, in the event of a human fault (i.e., contact by a human), the equivalent fault resistance will typically be relatively high (e.g., in the range of 500 Ω to 13.2 kΩ), which may be difficult to distinguish from the load.

Accordingly, some implementations have the advantage of facilitating the detection of L2L faults that correspond to the typical fault resistances which could occur in the event of inadvertent human contact with, for example, the output of an upconverter, the input of a downconverter, and/or between lines of a transmission line.

L2L fault impedance may have a wide range of values. Accordingly, since the output voltage of the upconverter is fixed, the energy absorbed by a fault will vary widely and will also be a function of the exposure time. In some implementations, the allowable fault current to which a human is allowed to be exposed is defined by standards (e.g., such as International Electrotechnical Commission™ (IEC) 60479-1 and −2.) Such standards may provide limit curves based on exposure time and magnitude of current flow.

In general, for a large fault current (low fault impedance) the allowable exposure time is relatively shorter, whereas for a small fault current (high fault impedance) the allowable exposure time is relatively longer. Accordingly, in some implementations, a protection system may respond relatively quickly to relatively larger fault currents but may take relatively more time to respond to relatively smaller fault currents. The larger a fault current is, the easier it is to distinguish from the load current. The smaller a fault current is, more difficult it is to distinguish from the load current. In some cases, this is because distinguishing a relatively smaller fault current from the load current would require detection circuitry with a large resolution and dynamic range, which may reduce the signal to noise ratio.

Upconverter circuitry 212 is configured to receive a suitable input power DC input voltage (e.g., from an AC to DC power converter) and to convert the DC input voltage to a higher, fixed transmission voltage ±v_{u,out} for transmission over transmission line 214. In this example, the nominal −48V is converted to a fixed +/−190V v_{u,out}. It is noted that these values are examples, and any suitable input voltage or fixed transmission voltage may be used in other implementations.

The output of upconverter circuitry 212 is connected to and/or in electrical communication with transmission line 214. Any suitable power transmission line or combination of lines, and/or circuitry, may be used as, may be included in, and/or may be used in place of transmission line 214. In some implementations, remote power system 200 can carry more power per independent channel than remote power system 100. In some implementations, transmission line 214 may include multiple conductors in parallel to reduce losses in implementations having only one upconverter and one downconverter. It is noted that in some implementations, system 100 would require many more transmission channels for a given load than system 200. For example, in some implementations, for a 1.3 kW load, 15 or 16 RFT-V channels (16 upconverters, 16 pairs of conductors, 16 downconverters) may be required in system 100, whereas for the same load, in some implementations, only 1 channel (1 upconverter, 1 downconverter, and 1 pair of cables (or potentially 2, depending on distance)) may be required. In some implementations, this has the advantage of providing significant savings in equipment.

Transmission line 214 is also connected to and/or in electrical communication with downconverter circuitry 216. In some implementations, transmission line 214 may run, for example, for many thousands of feet to load 204 (e.g., via downconverter 216). Downconverter circuitry 216 is configured to receive the fixed transmission voltage from transmission line 214 and to convert the transmission voltage to an appropriate voltage to provide to load 204. In some implementations, the appropriate voltage is a lower voltage. Load 204 includes any suitable electrical load, such as a telecommunications device, (e.g., a 5G small cell or mini-macro cell radio).

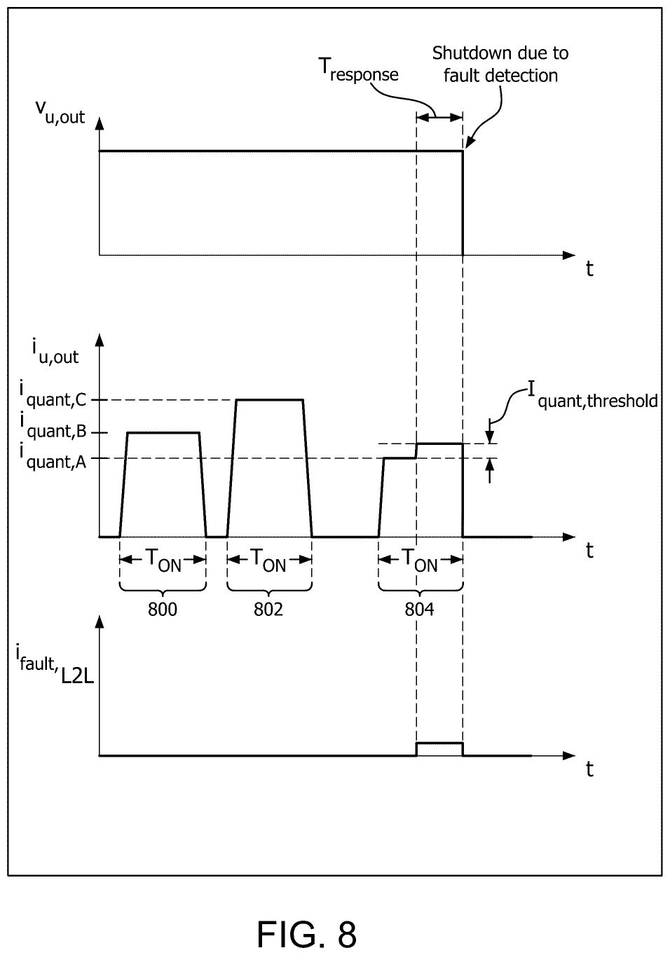

In this example, downconverter circuitry 216 provides output power (P_{d,out}) (e.g., it provides regulated output power compatible with load 204 while drawing input power in a way that is compatible with upconverter circuitry 212) to load 204. Upconverter circuitry 212 detects faults based on deviations from the predefined current characteristic of the input power, P_{d,in}, of downconverter circuitry 216, e.g., as further discussed herein. In some implementations, a predefined current characteristic of the input power, P_{d,in}, of downconverter circuitry 216 means that the shape of the current waveform is predefined and agreed between a compatible upconverter and a compatible downconverter. In some implementations, downconverter 216 draws a pulse of current of a predefined amplitude, a predefined duration, and a predefined minimum wait time between pulses. In some implementations, (e.g., as shown and described with respect to FIG. 8) the downconverter draws current at predefined levels (e.g., 0A, 1A, 2A, 3A), and the upconverter detects a fault as a deviation from one of these predefined values. For example, in some such implementations, if the upconverter detects a current of 1.2A, this is considered to be a fault because it is not at either the predefined current level of 1A, 2A, or any other predefined level.)

In some implementations upconverter circuitry 212 behaves as a voltage source, regulating its output voltage and providing any current that the downconverter draws. In some implementations, downconverter 216 controls the shape of the current it draws from its input using any suitable control strategy. In some implementations, downconverter 216 draws current in a predefined way, and upconverter 212 monitors the current to determine whether it matches the predefined current draw, where a substantial deviation (e.g., any deviation, or a deviation beyond a threshold current) is considered a fault.

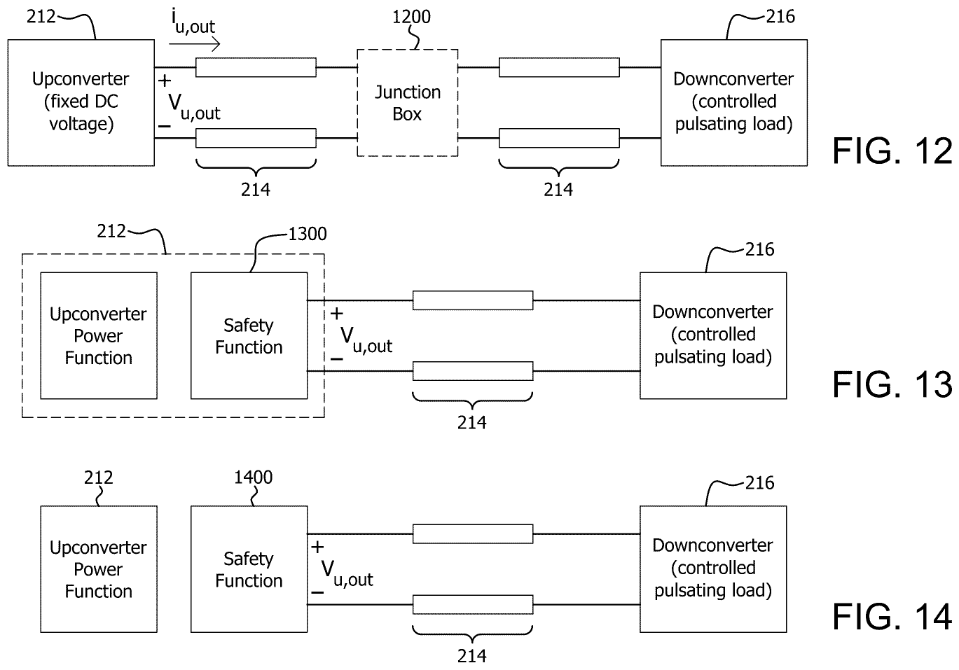

It is noted that the topology of FIG. 2 is exemplary only, and some implementations may include additional components, fewer components, or rearranged components. For example, FIG. 12 is a system diagram which shows portions of example remote power system 200, with the addition of a junction box 1200. Junction box 1200 may include surge protection and/or facility for disconnection of power to downconverter 216.

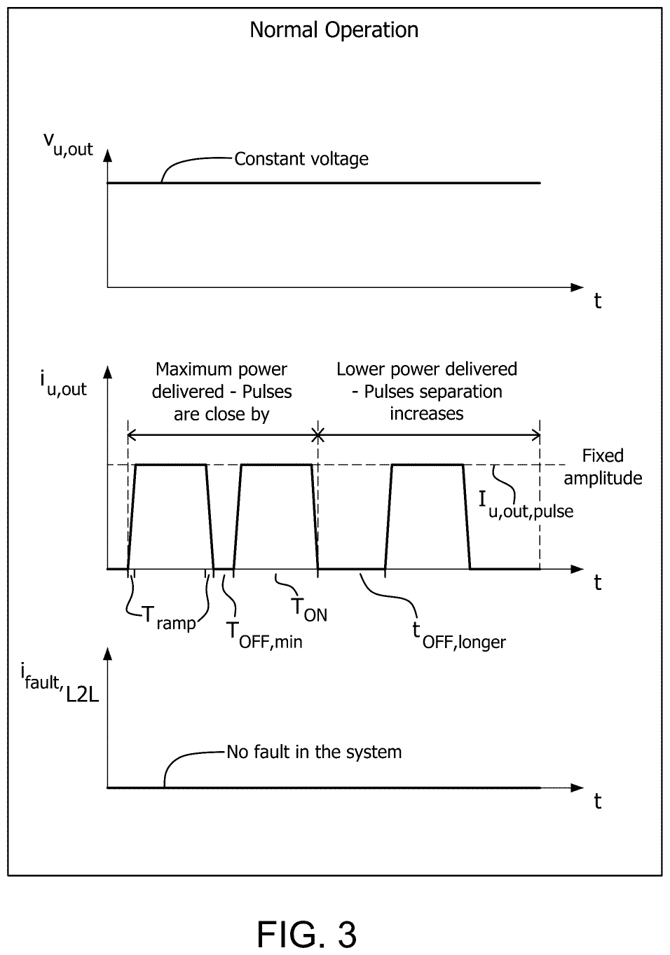

FIG. 3 is a line graph which shows the output voltage (v_{u,out}) and output current (v_{u,out}) of upconverter 212 as well as current due to faults (i_{fault,L2L}) in remote power system 200, with respect to time, under conditions where no fault occurs (“normal operation”).

Downconverter 216 is configured to draw current from transmission line 214 in a pattern of current pulses, each having a predefined ramp up/down time (Tᵣₐₘₚ), a predefined fixed pulse amplitude (I_{u,out,pulse}), and a predefined on-time (Tₒₙ). After downconverter 216 draws a current pulse, it dwells at 0 current for a predefined off time (T_{off}). In some implementations, t_{off} has a minimum value (T_{off,min}), which may be configured in downconverter 216. In some implementations, t_{off} changes based on the load 204 being powered by the downconverter 216.

Downconverter 216 provides regulated voltage v_{d,out} to load 204 based on a fixed v_{u,out} and a fixed amplitude of the pulsed i_{d,in}, and t_{off} is based on the load power p_{d,out} provided to load 204. Accordingly, t_{off} is relatively longer (i.e., the current pulses of i_{d,in} are further apart in time) when delivering relatively lower power to load 204, and t_{off} is relatively shorter (i.e., the current pulses of i_{d,in} are closer together in time) when delivering relatively greater power to load 204. During this operation, the output voltage v_{u,out} remains constant and the output current i_{u,out} of upconverter circuitry 212 is the same as the current input i_{d,in} to the downconverter.

It is noted that in some implementations the change in toff controls the downconverter input power p_{d,in}. In some implementations, since the I_{u,out,pulse} and Tₒₙ are fixed, the amount of energy transferred during the pulse (I_{u,out,pulse}*v_{u,out}*Tₒₙ) is fixed. In some implementations, the average power delivered to the downconverter is p_{d,in}=I_{u,out,pulse}*v_{u,out}*Tₒₙ/(Tₒₙ+t_{off}), by regulating t_{off}, the downconverter may regulate its average input power to match the need of the load. It is noted that these equations are simplified for illustrative purposes and, for example, do not account for the losses in the cable.

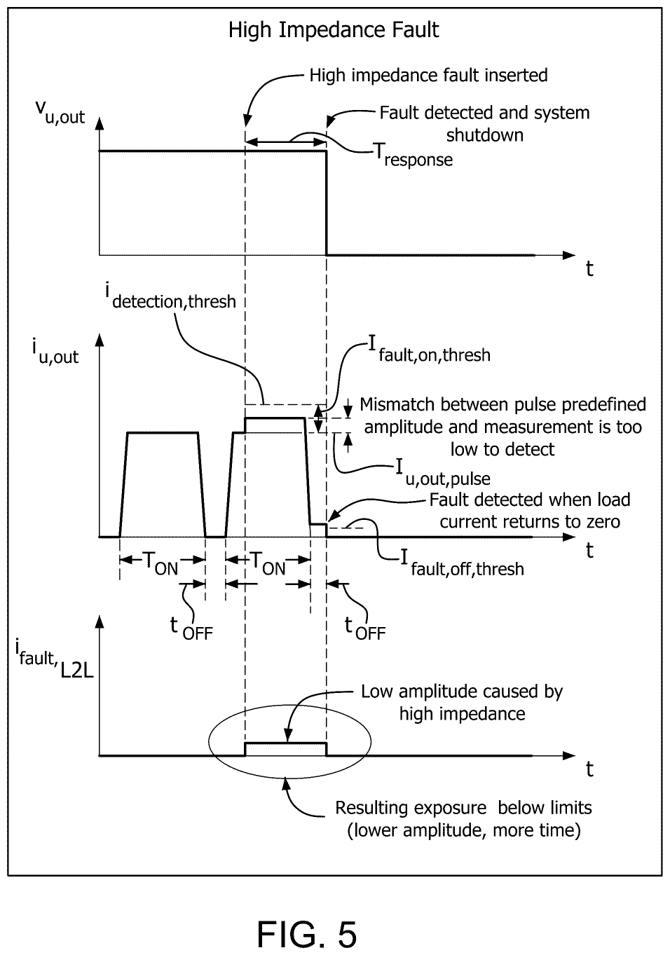

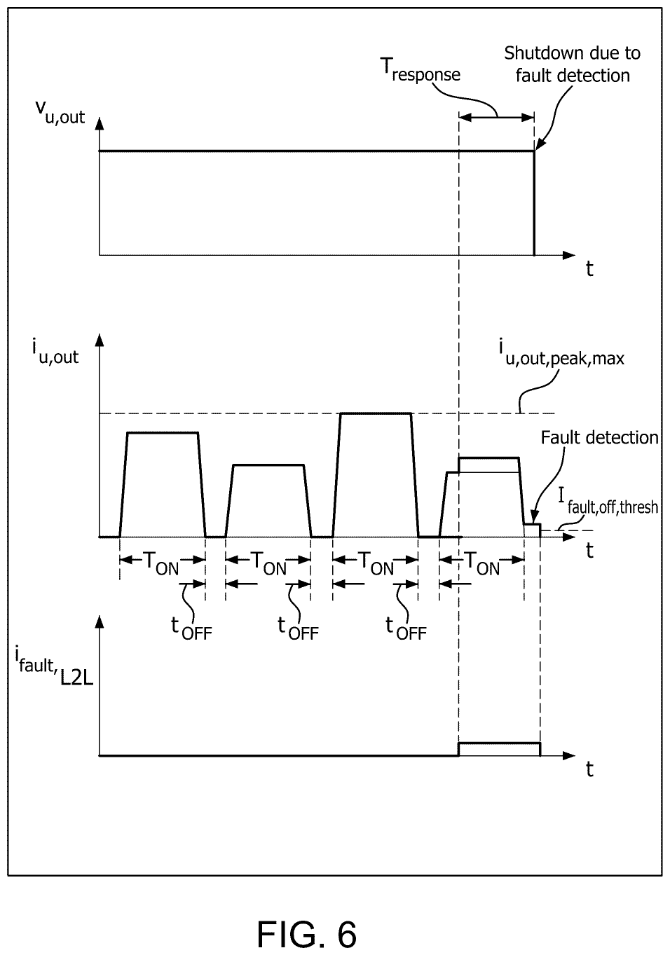

Accordingly, some implementations provide fault detection based on a downconverter drawing current in a specific manner. As discussed regarding FIG. 3, in some implementations, the downconverter (downconverter circuitry 216 in this example) draws pulses of current with a predefined shape. Using this approach, in some implementations, fault detection may be performed during, or based on, the current drawn during one or both of two different periods of time: the current on-time (tₒₙ—including the ramp times) and the current off-time (t_{off}). Examples of such fault detection are shown and described with respect to FIGS. 5 and 6, for low-impedance faults and high-impedance faults, respectively.

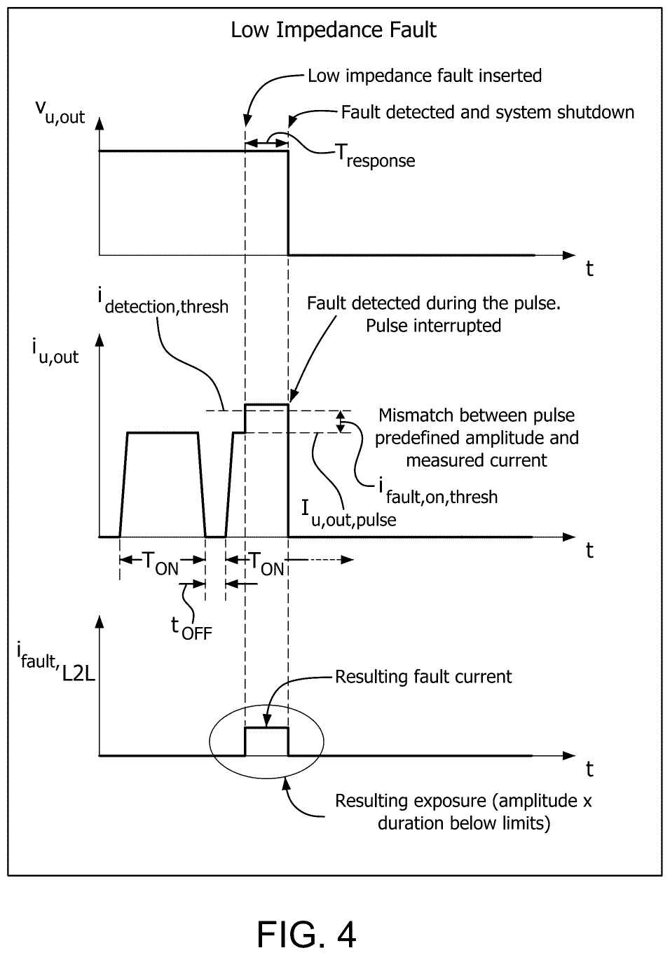

FIG. 4 is a line graph which shows the output voltage (v_{u,out}) and output current (i_{u,out}) of upconverter 212 as well as current due to L2L faults (i_{fault,L2L}) in remote power system 200, with respect to time, under conditions where a low-impedance fault occurs. In the example of FIG. 4, normal operation conditions as shown and described with respect to FIG. 3 prevail for the first current pulse of i_{u,out}, while a fault condition occurs during the second current pulse of i_{u,out}.

As shown in the example of FIG. 4, the downconverter (downconverter circuitry 216 in this example) draws a current pulse with a predefined amplitude I_{u,out,pulse} during tₒₙ. The detection threshold (i_{detection,thresh}) for detecting a fault during tₒₙ is set such that a fault will be detected if the measured output current i_{u,out} of the upconverter (upconverter circuitry 212 in this example) is larger than detection threshold i_{detection,thresh}. Detection threshold i_{detection,thresh} is the sum of the downconverter (downconverter circuitry 216 in this example) fixed pulse output current I_{u,out,pulse} and a large fault current threshold (i_{fault,on,thresh}) (shown in the FIG. 4). The large fault current threshold i_{fault,on,thresh} is set to be lower than the maximum allowed fault current for the tₒₙ duration (e.g., as defined in the current duration limits for human fault contacts as shown in appropriate standards, such as IEC 60479-1/2, or according to other standards or criteria).

For example, if the total tₒₙ period is 10 ms, the maximum current allowed through the fault may be i_{fault,on,thresh}=500 mA, based on the current duration limits for human fault contacts shown and described with respect to appropriate standards. In this example, if the fixed pulse output current I_{u,outpulse} for the tₒₙ period is set to 5A, in some implementations, the detection threshold i_{defection,thresh} is set below (e.g., just below) 5.5A.

If a fault current that exceeds the detection threshold i_{detection,thresh} occurs, as shown occurring during the second current pulse of i_{u,out} in FIG. 4, the fault is detected and the output voltage v_{u,out} of the upconverter is reduced below a safe level (e.g., is shut down), thus limiting the exposure of the fault to the current below the acceptable limits.

In this example, and other examples herein, the fault detection and remediation (e.g., comparing current with threshold and shutdown) is implemented in the upconverter (e.g., upconverter 212 as shown and described with respect to FIG. 2), however it is noted that this is exemplary only. For example, FIG. 13 is a system diagram which shows portions of example remote power system 200, illustrating example bifurcation of upconverter and safety function 1300 within upconverter 212, and FIG. 14 is a system diagram which shows portions of example remote power system 200, where the upconverter 212 and safety functions 1400 are implemented in separate devices (connected in series, in this example).

FIG. 5 is a line graph which shows the output voltage (v_{u,out}) and output current (i_{u,out}) of upconverter 212 as well as current due to L2L faults (i_{fault,L2L}) in remote power system 200, with respect to time, under conditions where a high-impedance fault occurs. In the example of FIG. 5, normal operation conditions as shown and described with respect to FIG. 3 prevail for the first current pulse of i_{u,out}, while a fault condition occurs during the second current pulse of i_{u,out}.

As shown in the example of FIG. 5, the downconverter (downconverter circuitry 216 in this example) draws a current pulse with a predefined amplitude I_{u,out,pulse} during tₒₙ. In this example, i_{u,out} never exceeds the detection threshold I_{defection,thresh} for detecting a fault during Tₒₙ, despite a fault condition beginning to occur during tₒₙ of the second current pulse. Accordingly, the fault current is not detected during tₒₙ of the second current pulse. In this example, the fault is not detected during tₒₙ since the fault current is less than I_{fault,on,thresh}, (and accordingly, the measured output current i_{u,out} of the upconverter (upconverter circuitry 212 in this example) and the fault (e.g., a human contacting the transmission line) will continue to be exposed to the fault current during the remaining tₒₙ period and into the t_{off} period.

During the t_{off} period, if a measured output current i_{u,out} of the upconverter exceeds a small fault current threshold I_{fault,off,thresh}, a fault is detected and the output voltage v_{u,out} of the upconverter is reduced below a safe level (e.g., is shut down), thus limiting the exposure of the fault to the current below the acceptable limits. In the example of FIG. 5, this occurs during the t_{off} period following the second current pulse.

The small fault current threshold I_{fault,off,thresh} is set below the lowest safe fault current based on the duration of t_{off}, e.g., as allowed by the appropriate safety standards. In some implementations, the small fault current threshold I_{fault,off,thresh} is typically less than 30 mA. The t_{off} fault threshold I_{fault,off,thresh} can be set to a relatively low value during this period because the downconverter is configured to not draw any load current during this time, and fault current is correspondingly easier to detect.

Accordingly, if the output current i_{u,out} of the upconverter (upconverter circuitry 212 in this example) exceeds the t_{off} fault threshold I_{fault,off,thresh} during the t_{off} period, then a fault has been detected and the output voltage v_{u,out} of the upconverter (upconverter circuitry 212 in this example) is reduced below a safe level, thus limiting the exposure of the fault to the current below the acceptable limits.

In the scenario described in FIG. 5, the current to which the fault is exposed during tₒₙ is acceptable, since the exposure duration will still be below the acceptable limits and the fault will be detected in the t_{off} period.

It is noted that a realized system will account for tolerances in components and the controllability of the current, and may include corresponding uncertainty bands in the analysis and setting of the thresholds. For example, tolerances in components (e.g., the variance of the sensing components) may result in errors in measurement (e.g., measuring a lower total current than it is actually present). In some implementations, this is accounted for in the selection of the fault thresholds. It is noted that in some implementations the uncertainty bands are not the same during tₒₙ and t_{off}. In some implementations, the uncertainty during the Tₒₙ is larger than the uncertainty during t_{off}; e.g., because at higher currents, greater errors in the sensing circuits and greater variance in the downconverter current from the ideal value are anticipated. In some implementations, a worst-case analysis is performed and thresholds are selected to account for worst-case scenarios.

Accordingly, some implementations have the advantage of compensating for these uncertainties by responding quickly to larger fault currents while also detecting small fault currents in enough time to avoid exceeding safety limits.

In some implementations, a realized system will account for the detection time interval and the response time of the upconverter to a fault current; e.g., because the fault (e.g., a human contacting the transmission line) is exposed from the instant the fault condition occurs until the instant the upconverter has reduced its output voltage to a safe level. In some implementations, the detection time interval refers to an interval between the moment that the fault enters the system (e.g., a person touches the conductors) and the moment where protection circuits detect that this has occurred. In some implementations, it will take some time for the protection circuits to determine an appropriate action (e.g., shut down) following the time that the protection circuits detect the fault. In some implementations, it will also take some time to remove energy from the system after an appropriate action has been determined which requires this (e.g., to reduce the voltage in the fault to 0V). During each of these time periods (the detection time, determination time, and energy removal time), the fault may be exposed to a hazardous voltage. Accordingly, in some implementations, the total time is accounted for in the design of aspects of the system (e.g., time periods, voltage and current thresholds, etc.).

In some implementations, in a realized system, the upconverter will differentiate between the start of a downconverter current pulse and a fault condition, and will account for the ramp rate and settling time of the downconverter. In this way, the upconverter will not confuse the beginning of a pulse, when the current is ramping up from 0A to the preset amplitude, as a fault. In some implementations, the differentiation can be performed through a predetermined handshaking mechanism between upconverter and downconverter.

Various configurations of the techniques described with respect to FIGS. 2-5 are also contemplated, including implementations where the measurements and/or predefined current pulses presented to the transmission line are different (e.g., in shape, amplitude, and/or spacing) than the measurements and/or predefined current pulses discussed with respect to FIGS. 2-5.

For example, FIG. 6 illustrates an example implementation that is substantially similar to the approach shown and described with respect to FIGS. 2-5, except in that instead of drawing a current pulse with a fixed amplitude and a variable t_{off}, the downconverter draws a current pulse with an indeterminate shape during a fixed Tₒₙ, and current measurement for fault detection occurs during t_{off} but not during tₒₙ. In this context, a current pulse with an indeterminate shape refers to a current where the shape of the pulse is not defined. For example, in some implementations, the pulse shape may be square, triangle, or any other desired shape during tₒₙ. After tₒₙ the current remains at zero for t_{off} to allow for detection. In some such implementations, this configuration can have the advantage of facilitating variable amplitude current pulses. In some such implementations, this configuration can have the advantage of facilitating fault protection based on measurements during the t_{off} period and without measurements during the tₒₙ period.

FIG. 6 is a line graph which shows the output voltage (v_{u,out}) and output current (i_{u,out}) of upconverter 212 as well as current due to L2L faults (i_{fault,L2L}) in remote power system 200. In the example of FIG. 6, normal operation conditions as shown and described with respect to FIG. 3 prevail for the first three current pulses of i_{u,out}, while a fault condition occurs during the fourth current pulse of i_{u,out}. It is noted that each of the current pulses of i_{u,out} have the same Tₒₙ but different amplitudes.

In the example of FIG. 6, the downconverter (e.g., downconverter circuitry 216 as shown and described with respect to FIG. 2) draws a current pulse with an indeterminate amplitude I_{u,out,pulse} during a fixed Tₒₙ. The downconverter thereafter draws no current during t_{off}. In this context, indeterminate amplitude refers to a pulse having any arbitrary amplitude and/or shape.

The upconverter does not monitor the system for fault current i_{fault,L2L} during tₒₙ, however, during t_{off}, the upconverter monitors the system for fault current i_{fault,L2L}. Any current detected above the t_{off} lowest safe fault current (I_{fault,off,thresh}) during t_{off} is indicative of a fault, and the upconverter reduces its output voltage v_{u,out} to a safe level (e.g., the upconverter shuts off). In some such implementations, the downconverter is configured to draw a current pulse with a fixed Tₒₙ and maximum current pulse peak amplitude (i_{u,out,peak,max}) having values set such that any expected fault does not exceed the acceptable limits.

Advantageously in some such implementations, because no fault detection occurs during Tₒₙ, the current pulse amplitude I_{u,out} drawn by the downconverter (downconverter circuitry 216 in this example) does not need to be fixed.

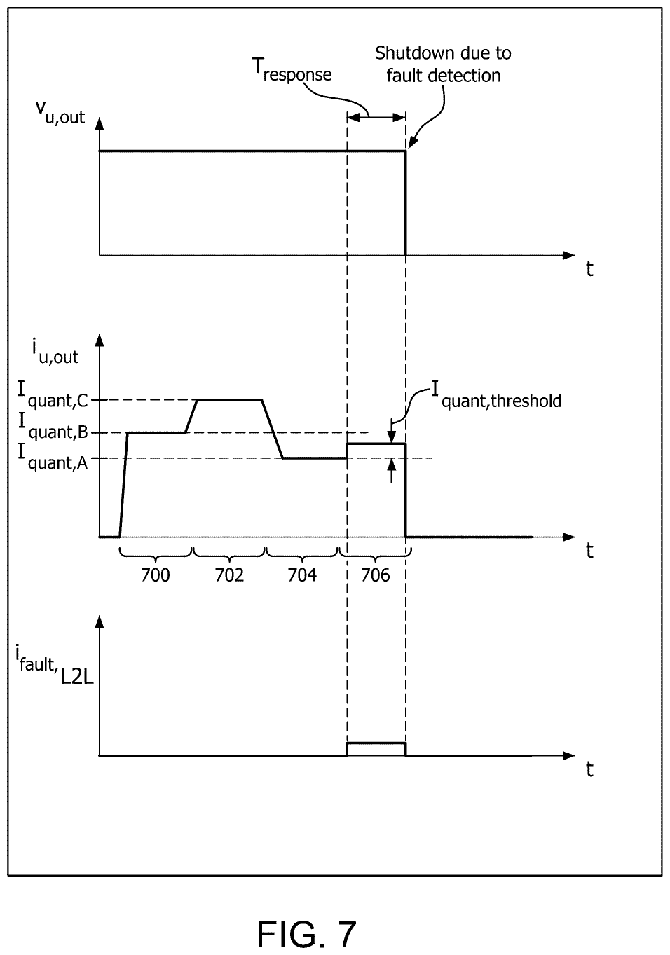

FIG. 7 is a line graph which illustrates an example implementation that is substantially similar to the approach shown and described with respect to FIGS. 2-5 above, except in that instead of drawing a current pulse with a fixed amplitude and a variable t_{off}, the downconverter draws continuous current flow at specific quantized current levels.

In some such implementations, these quantized levels have values such that the distance between the quantized levels is large enough to differentiate between an allowable load current and a fault current i_{fault,L2L}. In some such implementations, the upconverter measures the current i_{u,out} at its output and compares it against the allowed quantized current levels. The upconverter detects a fault if the current i_{u,out} does not match any of the allowed quantized levels within the band defined by a threshold amount that is indicative of a fault current i_{fault,L2L}. In some implementations, this approach has the advantage of facilitating continuous current flow and improved power transfer efficiency. In some implementations, this advantage is at the expense of more complicated current measurement and fault detection circuitry.

In the example of FIG. 7, i_{u,out} is equal to allowed quantized current level I_{quant,B} during time period 700, is equal to allowed quantized current level I_{quant,C} during time period 702, and is equal to allowed quantized current level I_{quant,A} during time period 704. During time period 706, i_{u,out} is not equal to any allowed quantized current level, and exceeds I_{quant,A} by a threshold amount I_{quant,threshold}. Accordingly, a fault has been detected and the output voltage v_{u,out} of the upconverter (upconverter circuitry 212 in this example) is reduced below a safe level, thus limiting the exposure of the fault to the current below the acceptable limits.

FIG. 8 illustrates an example implementation that is substantially similar to the approach shown and described with respect to FIGS. 2-5 above, except in that instead of drawing a current pulse with a fixed amplitude and a variable t_{off}, the downconverter draws current flow at specific quantized current levels during current pulses having a fixed Tₒₙ.

In some such implementations, these quantized levels have values such that the distance between the quantized levels is large enough to differentiate between an allowable load current and a fault current i_{fault,L2L}. In some such implementations, during tₒₙ, the upconverter measures the current i_{u,out} at its output and compares it against the allowed quantized current levels. The upconverter detects a fault if the current i_{u,out} does not match any of the allowed quantized levels within the band defined by a threshold amount that is indicative of a fault current i_{fault,L2L}. As in other approaches described herein, during the t_{off} period, the fault detection threshold is set below the lowest safe fault current and any current above this level will result in the upconverter reducing its output to a safe level. This method allows for longer pulse durations and improved power transfer efficiency at the expense of more complicated current measurement and fault detection.

In the example of FIG. 8, i_{u,out} is equal to allowed quantized current level I_{quant,B} during Tₒₙ time period 800, and is equal to allowed quantized current level I_{quant,C} during Tₒₙ time period 802. During Tₒₙ time period 804, i_{u,out} is not equal to any allowed quantized current level, and exceeds I_{quant,A} by a threshold amount I_{quant,threshold}. Accordingly, a fault has been detected and the output voltage v_{u,out} of the upconverter (upconverter circuitry 212 in this example) is reduced below a safe level, thus limiting the exposure of the fault to the current below the acceptable limits.

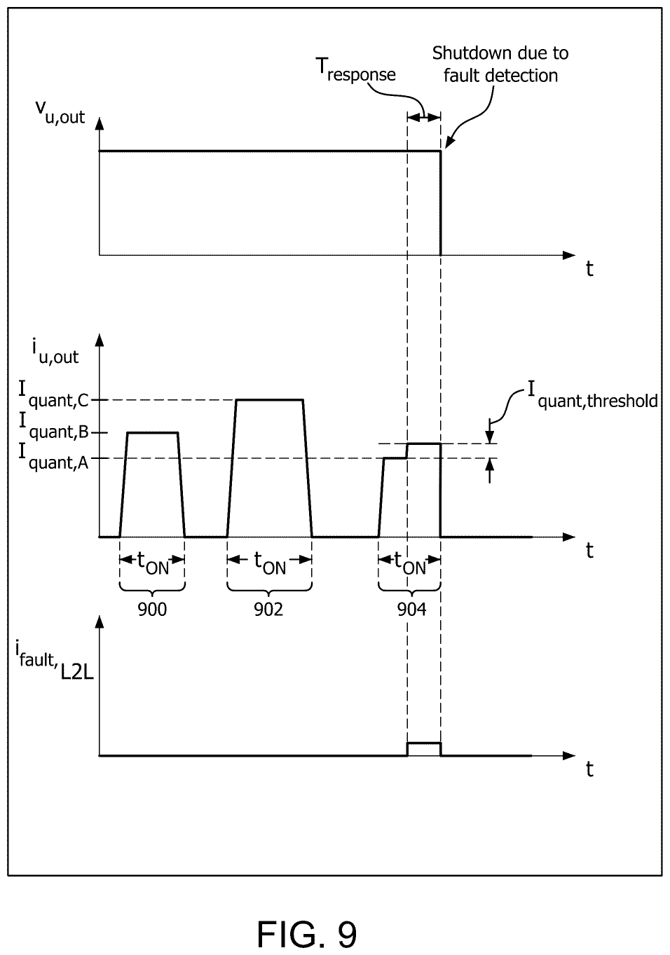

FIG. 9 illustrates an example implementation that is substantially similar to the approach shown and described with respect to FIG. 8 above, except in that instead of current flow at specific quantized current levels during current pulses having a fixed Tₒₙ, the downconverter draws current flow at specific quantized current levels during current pulses having a variable tₒₙ.

In the example of FIG. 9, these quantized levels have values such that the distance between the quantized levels is large enough to differentiate between an allowable load current and a fault current i_{fault,L2L}. In some such implementations, during tₒₙ, the upconverter measures the current i_{u,out} at its output and compares it against the allowed quantized current levels. The upconverter detects a fault if the current i_{u,out} does not match any of the allowed quantized levels within the band defined by a threshold amount that is indicative of a fault current i_{fault,L2L}. As in other approaches described herein, during the t_{off} period, the fault detection threshold is set below the lowest safe fault current and any current above this level will result in the upconverter reducing its output to a safe level. This method allows for longer pulse durations and improved power transfer efficiency at the expense of more complicated current measurement and fault detection.

In the example of FIG. 9, tₒₙ is different for each of the current pulses during time periods 900, 902, and 904. The current i_{u,out} is equal to allowed quantized current level I_{quant,B} during tₒₙ time period 900, and is equal to allowed quantized current level I_{quant,C} during tₒₙ time period 902. During tₒₙ time period 904, i_{u,out} is not equal to any allowed quantized current level, and exceeds I_{quant,A} by a threshold amount I_{quant,threshold}. Accordingly, a fault has been detected and the output voltage v_{u,out} of the upconverter (upconverter circuitry 212 in this example) is reduced below a safe level, thus limiting the exposure of the fault to the current below the acceptable limits.

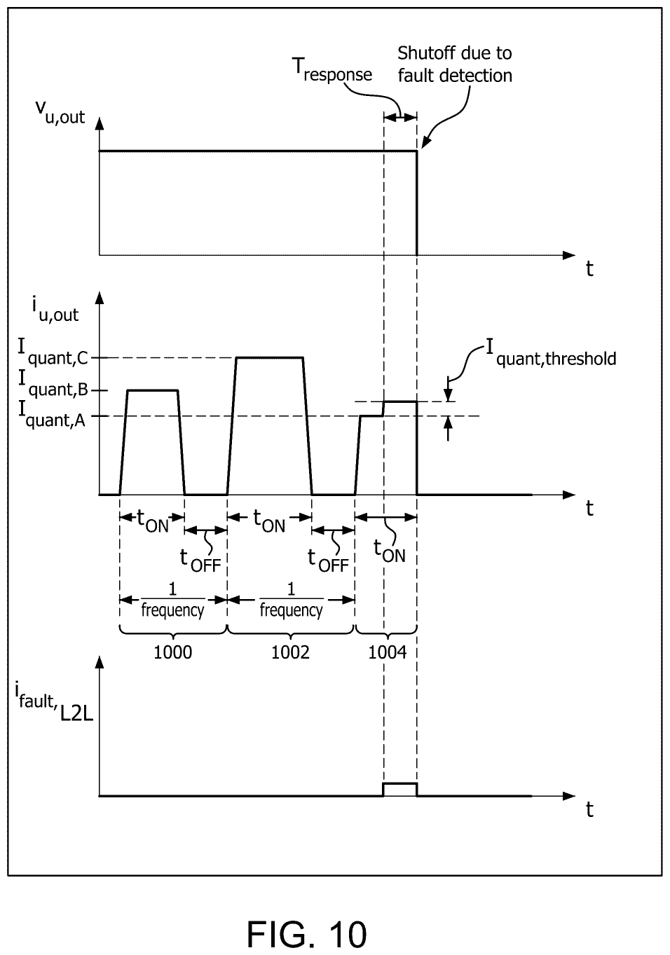

FIG. 10 illustrates an example implementation that is substantially similar to the approach shown and described with respect to FIG. 9, except in that, further to drawing a current flow at specific quantized current levels during current pulses having a variable tₒₙ, the current pulses occur at a fixed frequency.

In the example of FIG. 10, tₒₙ is different for each of the current pulses during time periods 1000, 1002, and 1004, but the leading edge of each current pulse occurs after a fixed time (1/frequency) from the leading edge of the previous leading edge. The current i_{u,out} is equal to allowed quantized current level I_{quant,B} during tₒₙ time period 1000, and is equal to allowed quantized current level I_{quant,C} during tₒₙ time period 1002. During tₒₙ time period 1004, i_{u,out} is not equal to any allowed quantized current level, and exceeds I_{quant,A} by a threshold amount I_{quant,threshold}. Accordingly, a fault has been detected and the output voltage v_{u,out} of the upconverter (upconverter circuitry 212 in this example) is reduced below a safe level, thus limiting the exposure of the fault to the current below the acceptable limits.

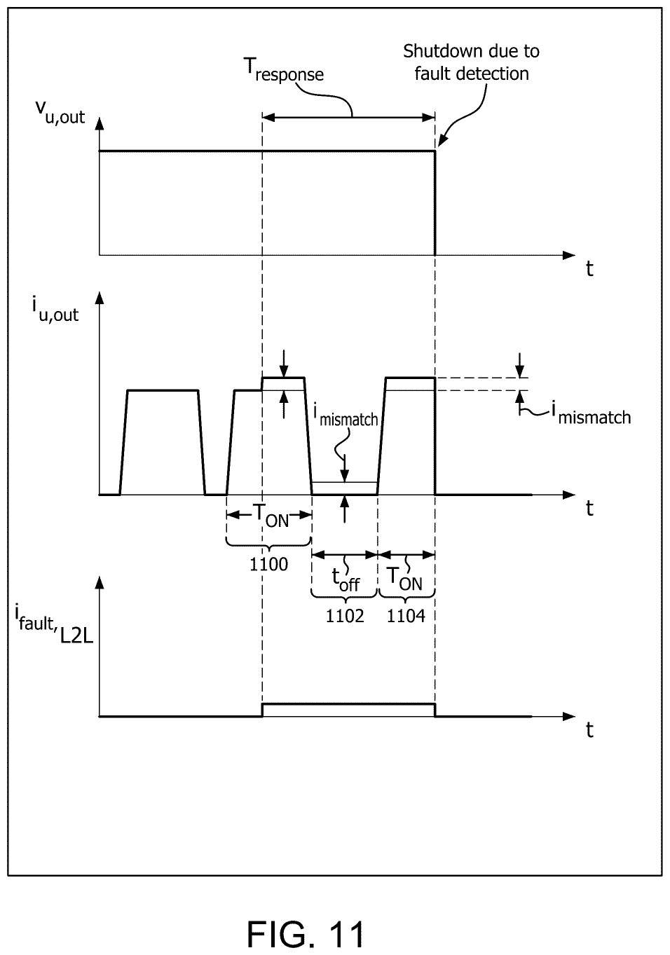

FIG. 11 illustrates an example implementation that is substantially similar to the approach shown and described with respect to FIGS. 2-5 above, except in that instead of detecting a fault based on the measured output current i_{u,out} of the upconverter exceeding detection threshold i_{detection,thresh} during a particular Tₒₙ, as in the example of FIG. 4, or based on measured output current i_{u,out} of the upconverter exceeding a small fault current threshold I_{fault,on,thresh} during a particular t_{off}, as in FIG. 5, the upconverter tracks an accumulated quantity (x) derived from any measured mismatch between the measured current and the predefined current pulse shape. When the tracked accumulated quantity (x) over time exceeds a threshold total X_{mismatch,threshold}, a fault is detected. The X_{mismatch,threshold} is set such that the exposure of the fault to the current is below the acceptable limits. It is noted that any suitable quantity may be tracked. For example, in some implementations, the tracked quantity X is charge, energy, or any other suitable quantity.

As shown in FIG. 11, there is a mismatch i_{mismatch} between the predefined current pulse and the measured current i_{u,out} during the Tₒₙ period 1100. A mismatch i_{mismatch} also occurs between the predefined current pulse and the measured current i_{u,out} during the t_{off} period 1102. A mismatch i_{mismatch} also occurs between the predefined current pulse and the measured current i_{u,out} during the Tₒₙ period 1104. Over the course of time periods 1100, 1102, 1104, the mismatched current i_{mismatch} is tracked and accumulated overtime. During time period 1104, the accumulated quantity (x) derived from the mismatched current i_{mismatch} exceeds a threshold total X_{mismatch,threshold}, and a fault is detected on this basis. Accordingly, the output voltage v_{u,out} of the upconverter (upconverter circuitry 212 in this example) is reduced below a safe level, thus limiting the exposure of the fault to the current below the acceptable limits.

In some implementations, the approach shown and described with respect to FIG. 11 has the advantage of facilitating a fault detection time (“trip time”) that is related to the severity of the fault, reducing the chance of false positives, at the expense of increasing the complexity by requiring to calculate the accumulated current mismatch.

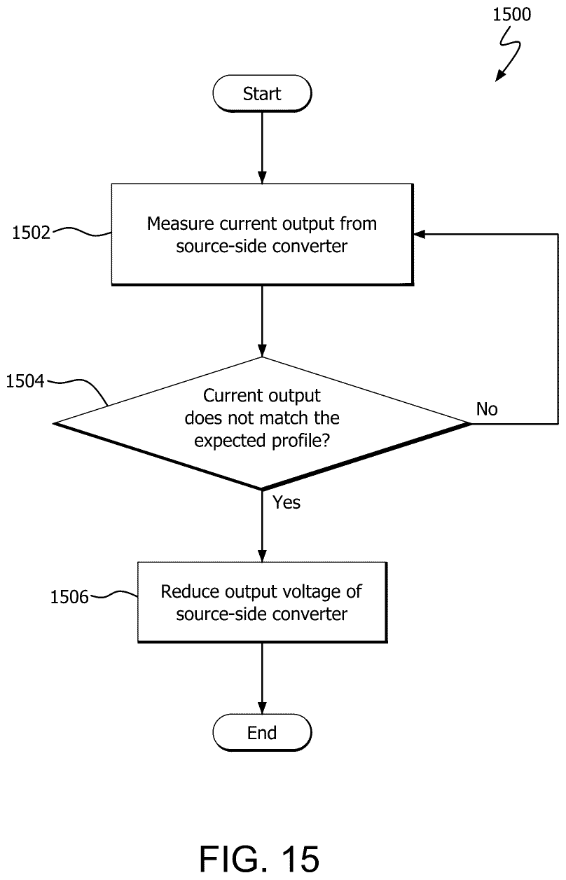

FIG. 15 is a flowchart illustrating an example method 1500 for detecting a fault in an electrical power system where electrical power is transferred from a source-side converter to a load-side converter via a transmission line. The method is implementable in any suitable power system, such as the examples shown and described herein.

In step 1502, a current output from the source-side converter to the load-side converter over the transmission line is measured during a time period from the beginning of a first current pulse of the current output to the beginning of a second current pulse of the current output.

On condition 1504 that the current output over time from the source-side converter exceeds a first current-duration limit during the time period, an output voltage of the source-side converter is reduced in step 1506. It is noted that the output voltage may be reduced as soon as the current output over time from the source-side converter exceeds the first current-duration limit during the time period, and the output voltage reduction does not need to await the end of the time period. In some implementations, the output voltage of the source-side converter is reduced on a condition that the current output over time from the source-side converter differs from a predetermined pulse-shaped load-side current, or any other condition as described herein.

In some implementations, the current output from the source-side converter exceeds the first current-duration limit during the time period by exceeding a first current limit during the first current pulse. An example of this scenario is shown and described with respect to FIG. 5. In some implementations, a predefined amplitude of the first current pulse and a predefined duration from the beginning of the first pulse to the end of the first pulse yield a current-duration that is less than the first current-duration limit. In some implementations, the first current limit is a quantized current limit and the current output from the source-side converter does not match the quantized current limit. Examples of this scenario are shown and described with respect to FIGS. 8-11

In some implementations, the current output from the source-side converter exceeds the first current-duration limit during the time period by exceeding a second current limit after the first current pulse. An example of this scenario is shown and described with respect to FIG. 5. In some implementations, a predefined amplitude of the first current pulse and the time period yield a current-duration that is less than the first current-duration limit. In some implementations, reducing an output voltage of the source-side converter includes disconnecting an output of the source-side converter from the transmission line.

It should be understood that many variations are possible based on the disclosure herein. Although features and elements are described above in particular combinations, each feature or element can be used alone without the other features and elements or in various combinations with or without other features and elements.

The methods or flow charts provided herein can be implemented in a computer program, software, or firmware incorporated in a non-transitory computer-readable storage medium for execution by a general-purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A method for detecting a fault in an electrical power system which includes a source-side converter in communication with a load-side converter via a transmission line, the method comprising:
measuring an output current from the source-side converter to the load-side converter over the transmission line during a time period from a beginning of a first current pulse of the output current to a beginning of a second current pulse of the output current; and
responsive to a profile of the output current differing from an expected profile of the output current during the time period, reducing an output voltage of the source-side converter.

2. The method of claim 1, wherein the expected profile of the output current comprises a current limit, and the output current differs from the expected profile by exceeding the current limit during the first current pulse.

3. The method of claim 1, wherein the expected profile of the output current comprises a current limit and the output current differs from the expected profile by exceeding the current limit after the first current pulse and before the second current pulse.

4. The method of claim 1, wherein the expected profile of the output current comprises a maximum current amplitude which varies during the time period.

5. The method of claim 1, wherein reducing the output voltage of the source-side converter comprises disconnecting an output of the source-side converter from the transmission line.

6. The method of claim 1, wherein reducing the output voltage of the source-side converter comprises turning off the source-side converter.

7. The method of claim 1, wherein the expected profile of the output current comprises a predefined pulse shape of the output current.

8. The method of claim 1, wherein the expected profile comprises a plurality of quantized current amplitudes.

9. The method of claim 8, wherein the output current differs from the expected profile by differing from all of the plurality of quantized current amplitudes.

10. The method of claim 1, wherein the expected profile of the output current comprises a maximum accumulated quantity limit, where the quantity is derived from the measurement of the output current over time.

11. The method of claim 1, further comprising tracking an accumulated quantity based on a difference between the output current and the expected profile, wherein the profile of the output current differs from the expected profile of the output current when the accumulated quantity exceeds a threshold.

12. A device configured to detect a fault in an electrical power system that includes a source-side converter in communication with a load-side converter via a transmission line, the device comprising:
circuitry configured to measure an output current from the source-side converter to the load-side converter over the transmission line during a time period from a beginning of a first current pulse of the output current to a beginning of a second current pulse of the output current; and
circuitry configured to reduce, responsive to a profile of the output current differing from an expected profile of the output current during the time period, an output voltage of the source-side converter.

13. The device of claim 12, wherein the expected profile of the output current comprises a current limit, and the output current differs from the expected profile by exceeding the current limit during the first current pulse.

14. The device of claim 12, wherein the expected profile of the output current comprises a current limit and the output current differs from the expected profile by exceeding the current limit after the first current pulse and before the second current pulse.

15. The device of claim 12, wherein the expected profile of the output current comprises a maximum current amplitude which varies during the time period.

16. The device of claim 12, wherein reducing the output voltage of the source-side converter comprises disconnecting an output of the source-side converter from the transmission line.

17. The device of claim 12, wherein reducing the output voltage of the source-side converter comprises turning off the source-side converter.

18. The device of claim 12, wherein the expected profile of the output current comprises a predefined pulse shape of the output current.

19. The device of claim 12, wherein the expected profile comprises a plurality of quantized current amplitudes.

20. The device of claim 19, wherein the output current differs from the expected profile by differing from all of the plurality of quantized current amplitudes.

21. The device of claim 12, wherein the expected profile of the output current comprises a maximum accumulated quantity limit, where the quantity is derived from the measurement of the output current over time.

22. The device of claim 12, further comprising circuitry configured to track an accumulated quantity based on a difference between the output current and the expected profile, wherein the profile of the output current differs from the expected profile of the output current when the accumulated quantity exceeds a threshold.
